(19) United States
(12) Patent Application Publication
(10) Pub. No.: US 2024/0268027 A1
(43) Pub. Date: Aug. 8, 2024

(54) CIRCUIT BOARD

(71) Applicant: Rolls-Royce Deutschland Ltd & Co KG, Blankenfelde-Mahlow (DE)

(72) Inventors: Stanley BUCHERT, Herzogenaurach (DE); Uwe WALTRICH, Forchheim (DE)

(21) Appl. No.: 18/569,529

(22) PCT Filed: Jun. 15, 2022
(86) PCT No.: PCT/EP2022/066361

§ 371 Date: Dec. 12, 2023

(30) Foreign Application Priority Data
Jun. 18, 2021 (DE) 10 2021 115 851.6

(51) Int. Cl. H05K 1/14; H05K 3/00; H05K 3/02; H05K 3/10

(52) U.S. Cl. CPC H05K 1/144; H05K 3/0091; H05K 3/022; H05K 3/101; H05K 2201/041

(57) ABSTRACT

A circuit board is disclosed that includes a plurality of circuit board layers located one on top of the other. The plurality of circuit board layers includes a topmost circuit board layer and a bottommost circuit board layer, wherein the topmost circuit board layer forms a top of the circuit board, wherein the bottommost circuit board layer forms a bottom of the circuit board, and wherein the plurality of circuit board layers together forms an end circuit-board edge that runs perpendicularly to the top and the bottom of the circuit board. The end circuit-board edge is provided with a coating made of an insulating material.

The present patent document is a § 371 nationalization of PCT Application Serial No. PCT/EP2022/066361, filed Jun. 15, 2022, designating the United States, and this patent document also claims the benefit of German Patent Application No. 10 2021 115 851.6, filed Jun. 18, 2021, which are incorporated by reference in their entireties.

### TECHNICAL FIELD

The disclosure relates to a circuit board that allows for effective use of all the regions of a circuit board.

### BACKGROUND

The practice of producing circuit boards from a multiplicity of prepregs (“pre-impregnated fibers”) and copper layers that are connected to one another and structured by laminating and etching processes is known. According to the standard EN IEC 60664-1, which relates to the design of air clearance and creepage distances, it is possible to assume a solid insulation between individual prepreg layers, and it is therefore unnecessary to comply with air clearance and creepage distances in this case. However, owing to delamination, for example, failure phenomena may occur along a prepreg layer, making it impossible to assume solid insulation between two potentials within a layer. Instead, a creepage distance is assumed in accordance with the standard mentioned. Here, the creepage distance is the shortest allowed distance between two conductive parts along the surface of an insulating material.

In this case, creepage distances between the layers of a circuit board are also maintained with respect to the circuit board edge. A housing or a heat sink may be situated adjacent to the circuit board edge, or there are additional creepage distances with respect to contact surfaces on the circuit board surfaces via the circuit board edge. Maintaining creepage distances in the layers of a circuit board, including toward the circuit board edge, disadvantageously leads to a relatively large unused edge region of the circuit board.

Moreover, an unused edge region also has a limiting effect on the thermal spread within a circuit board. If active components are integrated into or soldered onto the circuit board, it is advantageous to form a copper layer that is as sheet-like as possible below the component in which heat arises, which layer spreads this heat into the surface and thus increases the heat transfer surface via which heat may be transferred to a heat sink. On account of the creepage distance that has to be maintained with respect to the edge region, it is also not possible for a heat-spreading copper layer of this kind to extend as far as the edge region, and this limits heat transfer to a heat sink.

Known circuit board designs therefore require two-fold over-dimensioning. On the one hand, over-dimensioning of the circuit board in order to maintain the necessary air clearance and creepage distances with respect to the edge region. On the other hand, over-dimensioning of the assembly and/or of the heat sink due to limited thermal transfer.

### SUMMARY AND DESCRIPTION

The disclosure is based on the object of providing a circuit board that allows effective use of all the regions of a circuit board.

The scope of the present disclosure is defined solely by the appended claims and is not affected to any degree by the statements within this summary. The present embodiments may obviate one or more of the drawbacks or limitations in the related art.

Accordingly, a circuit board is disclosed that has a plurality of circuit board layers arranged one above the other. The plurality of circuit board layers includes an uppermost circuit board layer and a lowermost circuit board layer, wherein the uppermost circuit board layer forms an upper side of the circuit board, and the lowermost circuit board layer forms a lower side of the circuit board. The circuit board layers together form a circuit board end-face edge, which runs perpendicularly to the upper side and the lower side of the circuit board. The circuit board edge has a height that is substantially equal to the thickness of the circuit board.

The circuit board end-face edge is provided with a coating of an insulating material.

The disclosure is based on the concept of reducing or even completely avoiding air clearance and creepage distances that have to be maintained with respect to the edge of the circuit board by the targeted application of a coating of an insulating material to the end-face edge of the circuit board. The applied coating forms a materially integral solid insulator on the circuit board end-face edge which prevents the formation of creepage currents. The applied coating on the circuit board end-face edge provides a solid insulation within the individual layers of the circuit board.

As a result, the circuit board may be provided with a smaller unused edge region or no such edge region and may be reduced in size overall, thus enabling the required installation space and the use of material to be reduced. Moreover, there is the possibility that a heat-spreading copper layer in a circuit board of this kind extends further toward the circuit board end-face edge and, accordingly, forms a larger total surface, improving the thermal connection by increasing the proportion of copper in the circuit board and thereby allowing the achievement of smaller components. In this way, it is possible to minimize the necessary spacing between the copper layer around the circuit board edge as soon as it is possible to assume a solid insulation at the edge of the circuit board.

Another advantage associated with the disclosure includes increasing the robustness of the circuit board with respect to environmental influences at the critical circuit board edge, which is milled or scored, for example. For example, the edge coating with insulating material prevents moisture penetration into the circuit board on account of its inherent properties of low permeability to moisture and air.

As disclosed herein, an insulating material may refer to any non-conductor and thus any material, the electrical conductivity of which at 20° C. is less than 10⁻⁸ S·cm⁻¹ (or which has a specific resistance at 20° ° C. of over 10⁸ Ω·cm). Here, “S” is the unit of measure of the electrical conductivity. Refinements envisage that the resistance to creepage current provided by the insulating material has a CTI value (Comparative Tracking Index) that is at least 175, in the range of 175 to 600, or in the range of 400 to 600.

In one embodiment, the circuit board end-face edge is over-molded with the insulator in such a way that the coating extends over the circuit board edge onto the upper side and/or the lower side of the circuit board. For this purpose, provision is made, for example, for the coating to be formed in an edge strip on the lower side and/or in an edge strip on the upper side of the circuit board in addition to the circuit board end-face edge. An edge strip coated with insulating material on the upper side and/or on the underside of the circuit board protects the circuit board edge in an improved manner against environmental influences, e.g., the penetration of moisture. Moreover, the coated edge strips result in additional mechanical compressive stresses being applied to the circuit board edge, and these may counteract delamination of the circuit board starting from the edge, further increasing the life of the circuit board.

In another embodiment, the edge region of the circuit board is structured in such a way that it forms hollow structures filled with the insulating material at a distance from and/or adjacent to the circuit board end-face edge. In this case, the hollow structures may be configured as channels running perpendicularly to the upper side and the lower side of the circuit board and are spaced apart from the circuit board end-face edge, or for the hollow structures to be configured as channels running perpendicularly to the upper side and the lower side of the circuit board and extending as far as the circuit board end-face edge. The hollow structures may be introduced into the circuit board by standard processes in the manufacture of circuit boards, such as milling or drilling. The hollow structures filled with the insulating material improve the adhesion of the insulating material applied at the edge.

In principle, the insulating material used as a coating may be any insulating material. In certain embodiments, the insulating material is formed by a material that includes silicone, polyurethane, an epoxy resin, or a plastic.

In one embodiment, the coating of insulating material includes a material belonging to the material group of parylenes. Parylenes are hydrophobic, chemically resistant polymeric coating materials with a good barrier effect. One example of a parylene material is a plastic with the basic building block poly-p-xylylene, also referred to as parylene N. In certain examples, halogenated parylenes may be used.

One refinement of the disclosure provides that the insulating material provides insulation that meets the requirements of protection class 2 according to IEC 60664-3 and/or DIN VDE 0100-410 (VDE 0100-410):2018-10. According to one refinement, therefore, the coating is a coating of protection class 2. This provides materially integral solid insulation on the circuit board edge.

In principle, the coating of the circuit board end-face edge with an insulating material may be provided by numerous methods. In one embodiment, the coating of insulating material has been produced by chemical gas phase deposition. Such a method may be employed, for example, when using parylenes as an insulating material, wherein the parylene material is deposited in the gas phase. Here, there is the possibility of coating the circuit board edge in an electrically insulating manner with a homogeneous layer thickness.

In further embodiments, the coating of insulating material is produced by thermal spraying (e.g., including direct spraying from the side), nozzle coating using a nozzle through which the insulating material is applied directly to the surface of the circuit board end-face edge, or multicomponent injection molding, wherein the material is injection-molded onto the circuit board end-face edge.

According to one embodiment, the insulating material may extend in the circumferential direction of the circuit board along the entire circuit board end-face edge. According to this refinement, therefore, the circuit board end-face edge is provided with insulating material over its entire periphery. In other refinements, the insulating material may be formed only on some section or sections or points of the circuit board end-face edge, e.g., on edges of the circuit board or in sections in which components subject to high stresses are arranged or contacted.

As already observed, the circuit board may have at least one sheet-like copper layer formed and arranged in such a way that the layer spreads into the surface the heat of an active component integrated into the circuit board or is soldered onto the latter. In this case, the sheet-like copper layer extends substantially as far as the circuit board end-face edge, thereby improving the thermal connection of the circuit board.

The thickness of the coating of the circuit board end-face edge with insulating material is fundamentally dependent on the materials used, the temperatures which occur, the voltages applied, and other parameters. Refinements envisage that the layer thickness of the coating is in the range of 10 μm to 3 mm. For example, the layer thickness in the case of coating with parylene or an epoxy resin may be in the range of 10 μm to 50 μm, e.g., 30 μm. In the case where the edges are over-molded with polyurethane, the layer thickness may be in the millimeter range.

### BRIEF DESCRIPTION OF THE DRAWINGS

The disclosure is explained in greater detail below by a plurality of exemplary embodiments and with reference to the Figures of the drawing, in which:

FIG. 1 depicts schematically in section one embodiment of a circuit board, the circuit board end-face edge of which is provided with a coating of an insulating material.

FIG. 2 depicts schematically another embodiment of a circuit board, the circuit board end-face edge of which is provided with a coating of an insulating material, wherein the upper side and the lower side of the circuit board are also over-molded with the insulating material.

FIG. 3 depicts schematically another embodiment of a circuit board, the circuit board end-face edge of which is provided with a coating of an insulating material, wherein the circuit board edge is additionally structured with hollow structures, and FIG. 3 depicts two possible structuring options.

FIG. 4 depicts the exemplary embodiment of FIG. 3 in a section parallel to a circuit board plane.

FIG. 5 depicts a circuit board according to the prior art, which is arranged on a heat sink and delimits a housing.

FIG. 6 depicts schematically a circuit board that forms a sheet-like copper layer for cooling a soldered-on component.

FIG. 7 depicts schematically a circuit board that forms a sheet-like copper layer for cooling a component integrated into the circuit board.

### DETAILED DESCRIPTION

For a better understanding of the background of the present disclosure, a circuit board arrangement is described on the basis of FIGS. 5 to 7.

FIG. 5 shows a circuit board 1 that includes a multiplicity of circuit board layers 10 arranged one above the other. In this case, an uppermost circuit board layer forms an upper side 11 of the circuit board 1 and a lowermost circuit board layer forms an underside 12 of the circuit board 1. The circuit board layers 10 together form a circuit board end-face edge 15. The circuit board 1 is, for example, arranged on a heat sink 6 with cooling fins 61, which may be connected to the ground potential. The circuit board edge 15 may be arranged at a distance from a housing 6.

The individual circuit board layers 10 are formed, for example, by prepreg layers, (e.g., glass fiber mats impregnated with epoxy, and copper layers), which are connected to one another and structured in a manner known per se by laminating and etching processes. The contours of the circuit board 1 are achieved by milling and drilling processes. According to the standard EN IEC 60664-1, which relates to the design of air clearance and creepage distances, it is assumed that there is solid insulation between individual prepreg layers (in the vertical direction in FIG. 5), and it is therefore unnecessary to comply with air clearance and creepage distances between prepreg layers. Along a prepreg layer (horizontal plane in FIG. 5), however, there is the risk of failure phenomena, e.g., those due to delamination of the prepreg layers, and it is therefore not possible to assume solid insulation between two potentials within a layer. Accordingly, it is necessary within a prepreg layer to take account of creepage distances that indicate the shortest allowed distance along the surface between two conductive parts. FIG. 5 shows such a creepage distances 71 and an air clearance 72 with respect to the housing 7. Here, the creepage distances 71 may extend over the circuit board end-face edge 15.

Creepage distances 71 that have to be taken into account within a layer 10 is also maintained in each layer 10 with respect to the end-face edge 15 of the circuit board 1. Accordingly, an edge region A of the circuit board 1 may be kept free from components, conductor tracks, and contacts toward the end-face edge 15. This leads to a relatively large unused edge region A of the circuit board 1.

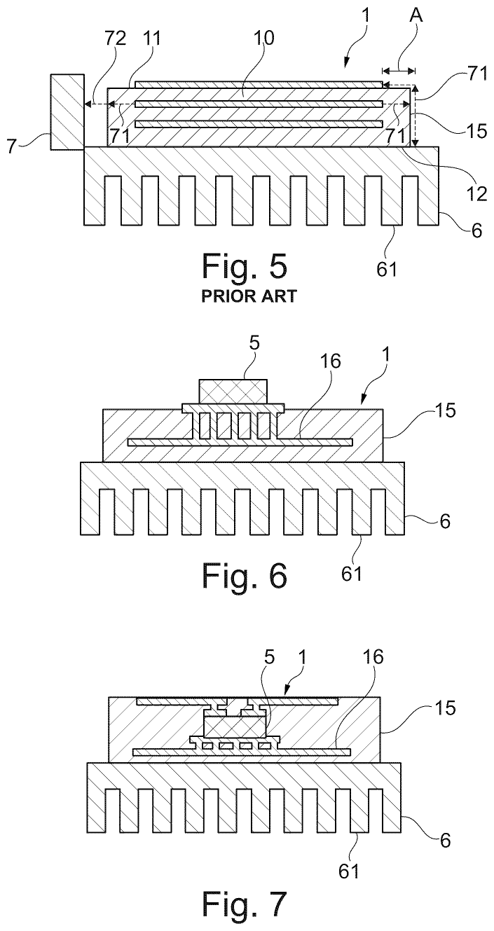

The edge region A to be kept free also has a limiting influence on the “thermal spread” within the circuit board 1, as explained with reference to FIGS. 6 and 7. FIG. 6 shows a circuit board 1 with an active component 5 soldered onto the circuit board 1. FIG. 7 shows a circuit board 1 with an active component 5 integrated into the circuit board 1. In both cases, the circuit board 1 includes, as one of its layers 10, a copper layer 16 of sheet-like design that spreads the heat output by the component 5 into the surface and thus increases the heat transfer surface. Here, it is also possible for the heat-transferring copper layer 16 not to be formed in the edge region A.

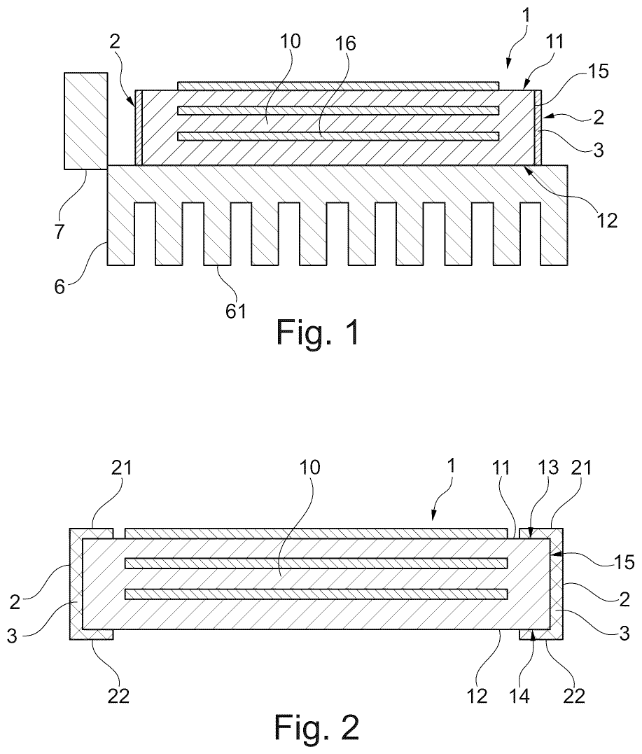

FIG. 1 shows a first exemplary embodiment of a circuit board. The circuit board 1 includes a multiplicity of circuit board layers 10, which are arranged one above the other. In this case, an uppermost circuit board layer forms an upper side 11 of the circuit board 1 and a lowermost circuit board layer forms an underside 12 of the circuit board 1. The circuit board layers 10 together form a circuit board end-face edge 15, the height of which corresponds to the thickness of the circuit board 1. The circuit board 1 is arranged on a heat sink 6 having cooling fins 61. The circuit board edge 15 is arranged at a distance from a housing 6. In respect of the design of the circuit board layers 10, attention is drawn to the description of FIGS. 5-7. The circuit board layers 10 are thus formed, for example, by prepreg layers and copper layers, between which a distinction is made only schematically in the illustration in FIG. 1.

The end-face edge 15 of the circuit board is provided with a coating 2 of an insulating material 3. The insulating material 3 provides solid insulation at the edge of the circuit board 1. As a result, the formation of a creepage current is prevented, and the robustness of the circuit board 1 with respect to environmental influences is improved.

In principle, the insulating material 3 may be formed by any desired non-conductor. For example, this is a coating 2 of silicone, polyurethane, or an epoxy resin. The insulating material 3 provides an insulator that meets the requirements of protection class 2 according to IEC 60664-3.

In one exemplary embodiment, the insulating material 3 is formed from a material that belongs to the material group of parylenes. Accordingly, the coating 2 is a parylene coating. This may be deposited in the gas phase and offers the possibility of coating the circuit board edge 15 in an electrically insulating manner with a homogeneous layer thickness in the range of 10 μm to 100 μm, for example.

Owing to its insulating properties, such a coating 2 prevents the formation of a current. Moreover, it is resistant to environmental influences such as moisture, noxious gases, and temperature, and offers very high gap penetration in order to coat even micro cracks in the edge of the prepreg layers. Hydrophobic properties of the coating material and low permeability to moisture and air protect the circuit board 1 from the penetration of unwanted moisture and other noxious gases. Particularly at the edge 15 of the circuit board 1, which may be milled, it is possible for damaged glass fibers or microscopic delamination to form, starting from which the circuit board 1 degrades if it is formed without a protective coating 2.

According to FIG. 1 and with reference to FIGS. 6 and 7, the circuit board layers 10 may also have at least one sheet-like copper layer 16, which serves to spread the heat of an active component (not illustrated in FIG. 1) into the surface. Owing to the coating 2 of the end-face region 15, a sheet-like copper layer of this kind may extend further as far as the end-face region 15 than would be possible without the coating 2. In the schematic illustration in FIG. 1, however, this is not illustrated specifically.

In principle, the coating 2 of the insulating material 3 may be applied by many coating methods. Examples thereof are chemical gas phase deposition, thermal spraying, nozzle coating, or multicomponent injection molding.

The coating 2 of insulating material 3 may be formed at the end-face edge 15 along the entire periphery of the circuit board 1, or alternatively may be formed only in some section or sections or points.

FIG. 2 shows an exemplary embodiment of a circuit board 1, the fundamental construction of which corresponds to the construction of the circuit board 1 in FIG. 1, and therefore reference may be made to the statements in this regard. As an addition to the exemplary embodiment in FIG. 1, provision is made for the coating 2 to extend beyond the circuit board edge 15 onto the upper side 11 and the lower side 12 of the circuit board 1. In this case, an upper coating region 21 of the coating 2 covers an upper edge strip 13 of the circuit board 1, and a lower coating region 22 of the coating 2 covers a lower edge strip 14 of the circuit board 1.

By such a refinement, the robustness of the circuit board 1 with respect to environmental influences is further improved. Moreover, the situation is such that the edge coating 21, 22 of the upper side 11 and of the underside 12 lead to the introduction of mechanical compressive stresses into the circuit board edge which additionally counteract any possible delamination of prepreg layers starting from the circuit board edge.

The application of the coating 2 with the coating regions 21, 22 may be accomplished by deposition from the gas phase, as explained with reference to FIG. 1. Alternatively, provision may be made for the insulating material 3 to be injected around the edge region of the circuit board 1 under temperature and pressure. As explained with reference to FIG. 1, the insulating material 3 may be polyurethane or other plastics or silicone, for example.

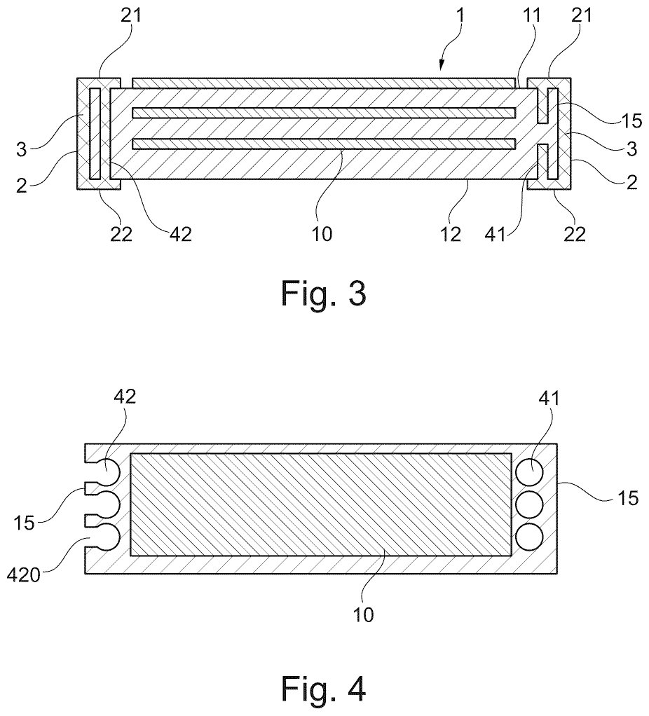

FIGS. 3 and 4 show an exemplary embodiment that builds on the exemplary embodiment in FIG. 2 in which structures 41, 42 that improve the connection and adhesion of the coating 2 to the circuit board 1 are additionally integrated into the edge region of the circuit board 1. In this case, FIGS. 3 and 4 show two different variant embodiments of such structures 41, 42. An actual form of implementation would not necessarily implement both structural variants but only one of these variants.

Attention is drawn to the fact that FIG. 4 illustrates a section along one of the layers 10 in FIG. 3, and therefore a layer 10 is thus as it were viewed from above.

On the right-hand side of FIGS. 3 and 4, a hollow structure 41 is implemented that is formed by the holes or channels that extend perpendicularly at a distance from the circuit board end-face edge 15. In this case, the hollow structures 41 are likewise filled with insulating material 3. As may be seen from FIG. 3, the hollow structures 41 are filled with insulating material, starting from the upper and lower coating regions 21, 22 of the coating 2.

On the left-hand side of FIGS. 3 and 4, a hollow structure 42 is implemented, which is formed by the holes or channels that extend as far as the circuit board end-face edge 15 and form openings 420 thereto. In this case, the hollow structures 42 are likewise filled with insulating material 3. By virtue of the openings 420, the hollow structures 42 may be filled with insulating material 3 from the end face 15 without this necessarily taking place via upper and lower coating regions 21, 22 of the coating 2.

The disclosure is not limited to the embodiments described above, and various modifications and improvements may be made without departing from the concepts described here. It is furthermore to be noted that any of the features described may be used separately or in combination with any other features, provided that they are not mutually exclusive. The disclosure extends to and includes all combinations and sub-combinations of one or more features which are described here. If ranges are defined, these ranges therefore include all the values within these ranges as well as all the partial ranges that lie within a range.

It is to be understood that the elements and features recited in the appended claims may be combined in different ways to produce new claims that likewise fall within the scope of the present disclosure. Thus, whereas the dependent claims appended below depend on only a single independent or dependent claim, it is to be understood that these dependent claims may, alternatively, be made to depend in the alternative from any preceding or following claim, whether independent or dependent, and that such new combinations are to be understood as forming a part of the present specification.

While the present disclosure has been described above by reference to various embodiments, it may be understood that many changes and modifications may be made to the described embodiments. It is therefore intended that the foregoing description be regarded as illustrative rather than limiting, and that it be understood that all equivalents and/or combinations of embodiments are intended to be included in this description.

1. A circuit board comprising:
a plurality of circuit board layers arranged one above the other,
wherein the plurality of circuit board layers comprises an uppermost circuit board layer and a lowermost circuit board layer,
wherein the uppermost circuit board layer forms an upper side of the circuit board,
wherein the lowermost circuit board layer forms a lower side of the circuit board,
wherein the circuit board layers together form a circuit board end-face edge that runs perpendicularly to the upper side and the lower side of the circuit board, and
wherein the circuit board end-face edge is provided with a coating of an insulating material.

2. The circuit board of claim 1, wherein the circuit board end-face edge is over-molded with the insulating material such that the coating extends over the circuit board end-face edge onto the upper side and/or the lower side of the circuit board.

3. The circuit board of claim 2, wherein the coating is formed in an edge strip on the upper side and/or in an edge strip on the lower side of the circuit board in addition to the circuit board end-face edge.

4. The circuit board of claim 1, wherein an edge region of the circuit board is structured such that the edge region comprises hollow structures filled with the insulating material at a distance from and/or adjacent to the circuit board end-face edge.

5. The circuit board of claim 4, wherein the hollow structures are configured as channels running perpendicularly to the upper side and the lower side of the circuit board, and
wherein the hollow structures are spaced apart from the circuit board end-face edge.

6. The circuit board of claim 4, wherein the hollow structures are configured as channels running perpendicularly to the upper side and the lower side of the circuit board, and
wherein the hollow structures extend as far as the circuit board end-face edge.

7. The circuit board of claim 1, wherein the coating of the insulating material comprises silicone, polyurethane, or an epoxy resin.

8. The circuit board of claim 1, wherein the coating of the insulating material comprises a material belonging to a material group of parylenes.

9. The circuit board of claim 1, wherein the insulating material is configured to provide insulation that meets requirements of protection class 2 according to IEC 60664-3 and/or DIN VDE 0100-410 (VDE 0100-410):2018-10.

10. The circuit board of claim 1, wherein the coating of the insulating material has been produced by chemical gas phase deposition.

11. The circuit board as of claim 1, wherein the coating of the insulating material has been produced by thermal spraying, nozzle coating, or multicomponent injection molding.

12. The circuit board of claim 1, wherein the insulating material extends in a circumferential direction of the circuit board along an entire circuit board end-face edge.

13. The circuit board of claim 1, wherein the insulating material is formed only on some section or sections or points of the circuit board end-face edge less than an entire circuit board end-face edge.

14. The circuit board of claim 1, wherein the circuit board has at least one sheet-like copper layer arranged such that the at least one sheet-like copper layer spreads heat of an active component into a surface of the at least one sheet-like copper layer, and
wherein the active component is integrated into the circuit board or is soldered onto the circuit board.

15. The circuit board of claim 14, wherein the at least one sheet-like copper layer extends as far as the circuit board end-face edge.

16. The circuit board of claim 1, wherein a layer thickness of the coating is in a range of 10 μm to 3 mm.
